(19) United States
(12) Patent Application Publication
(10) Pub. No.: US 2025/0067623 A1
(43) Pub. Date: Feb. 27, 2025

(54) SUBSTRATE PROCESSING DEVICE AND DEFECT DETECTION METHOD FOR SUBSTRATE PROCESSING DEVICE

(71) Applicant: SEMES CO., LTD., Cheonan-si (KR)

(72) Inventors: Jong Hak CHOI, Suwon-si (KR); Wan Hee HAN, Cheonan-si (KR); Han Seon KANG, Seoul (KR); Jung Min YOON, Pyeongtaek-si (KR); Dae Il JANG, Seoul (KR)

(73) Assignee: SEMES CO., LTD., Cheonan-si (KR)

(21) Appl. No.: 18/791,704

(22) Filed: Aug. 1, 2024

(30) Foreign Application Priority Data
Aug. 23, 2023 (KR) 10-2023-0110651

(51) Int. Cl. G01M 13/045; G01M 99/00

(52) U.S. Cl. CPC G01M 13/045; G01M 99/005

(57) ABSTRACT

Disclosed is a device for processing a substrate, the device including: a support unit including a spin chuck supporting a substrate, a rotation shaft supporting the spin chuck, and a driver providing rotational force to the rotation shaft; and a determination unit for determining whether the rotation shaft is defective, in which the determination unit determines whether the rotation shaft is defective based on a current value applied to the driver while the rotation shaft is rotating.

### CROSS-REFERENCE TO RELATED APPLICATIONS

This application claims priority to and the benefit of Korean Patent Application No. 10-2023-0110651 filed in the Korean Intellectual Property Office on Aug. 23, 2023, the entire contents of which are incorporated herein by reference.

### TECHNICAL FIELD

The present invention relates to a substrate processing device and a defect detection method for the substrate processing device.

### BACKGROUND ART

To manufacture semiconductor devices, various processes, such as photography, deposition, ashing, etching, and ion implantation, are performed. In addition, before and after these processes are performed, a cleaning process of cleaning particles remaining on the substrate is performed.

The above processes may also be performed with the substrate supported on the support unit rotated. For example, in a cleaning process, chemicals, deionized water (DIW), and organic solvents are supplied to the substrate which is rotated while being supported on the support unit. In addition, in an etching process, a wet etching process supplies an etchant to the substrate which is rotated while being supported on the support unit.

As such, the process is carried out while the substrate is rotating, and in this case, the support unit that rotates the substrate includes a rotation shaft connected to a chuck to which the substrate is connected, and the rotation shaft rotates at a high speed to rotate the substrate.

As a result, the conventional rotation shaft wears out the parts that are connected to the chuck when rotating at high speeds and generate dust, and the generated dust affects the processing process of the substrate.

For this reason, the conventional support unit performs the inspection by periodically measuring the vibration of the rotation shaft while the process is stopped, which is too time-consuming for the inspection.

As an alternative, the conventional support unit may predict the presence of defects in the rotation shaft by analyzing the pattern form of the amount of current required for rotation, but there are many variables to consider, making it difficult to predict defects in the rotation shaft.

### SUMMARY OF THE INVENTION

The present invention has been made in an effort to provide a provide a substrate processing device and a defect detection method for the substrate processing device that may easily determine whether a rotation shaft is defective only by analyzing a pattern of current values.

The object of the present invention is not limited thereto, and other objects not mentioned will be clearly understood by those of ordinary skill in the art from the following description.

An exemplary embodiment of the present invention provides a device for processing a substrate, the device including: a support unit including a spin chuck supporting a substrate, a rotation shaft supporting the spin chuck, and a driver providing rotational force to the rotation shaft; and a determination unit for determining whether the rotation shaft is defective, in which the determination unit determines whether the rotation shaft is defective based on a current value applied to the driver while the rotation shaft is rotating.

According to the exemplary embodiment, the determination unit may include an abnormality diagnosis model in which a relationship between the current value and a state of the rotation shaft is preset, and whether the rotation shaft is defective may be determined by the abnormality diagnosis model.

According to the exemplary embodiment, the abnormality diagnosis model may have a correlation between the current value and the state of the rotation shaft as data based on a correlation between vibration of the rotation shaft and the state of the rotation shaft and a correlation between the vibration of the rotation shaft and the current value, and determine whether the rotation shaft is defective based on the current value in the data.

According to the exemplary embodiment, the data may include current abnormality patterns formed in a form of a DB.

According to the exemplary embodiment, the support unit may further include a bearing connected to the rotation shaft, and the defect in the rotation shaft may include a defect due to wear with the bearing.

According to the exemplary embodiment, the driver may include a motor, and the determination unit may detect a torque value of the motor, converts the torque value to a current value, and determine whether the rotation shaft is defective.

According to the exemplary embodiment, the abnormality diagnosis model may detect a time point at which a defect of the rotation shaft occurs by vibration measurement, and recognize a change pattern of the current value from the detected time point as an abnormality pattern to determine whether the rotation shaft is defective.

According to the exemplary embodiment, a vibration value measured when measuring the vibration may be measured by an acceleration for vibration of the support unit.

According to the exemplary embodiment, a vibration value measured when measuring the vibration may be measured by the amount of displacement for vibration of the support unit.

According to the exemplary embodiment, a vibration value measured when measuring the vibration may be measured by a sound generated by the vibration of the support unit.

According to the exemplary embodiment, the determination unit may include: a vibration detection unit installed on the support unit to measure a vibration value of the support unit; a current detection unit electrically connected with the support unit to detect a current value applied to a motor rotating the support unit; and an inspection unit that receives the vibration value and the current value from the vibration detection unit and the current detection unit as inputs, determines an error in rotation of the support unit based on the vibration value, and determines an abnormality in rotation of the substrate by applying an abnormality diagnosis model to the current value from a time point at which the error in rotation of the support unit is determined.

Another exemplary embodiment of the present invention provides a defect detection method for a substrate processing device, the defect detection method determining whether a rotation shaft is defective when a support unit that includes a rotation shaft and supports a substrate processes the substrate while rotating the substrate, the defect detection method including: generating an abnormality diagnosis model in which a correlation between a current value and a state of the rotation shaft is preset; and determining, by the abnormality diagnosis model, whether the rotation shaft is defective based on the current value applied to a driver that rotates the rotation shaft while the rotation shaft is rotating.

According to the exemplary embodiment, the generating of the abnormality diagnosis model may include: a vibration detection unit mounting operation of mounting a vibration detection unit on a support unit including the rotation shaft; a rotation shaft rotating operation of rotating the rotation shaft; a vibration value detecting operation of detecting, by the vibration detection unit, a vibration value of the rotation shaft; an abnormality time detecting operation of receiving, by an inspection unit, the vibration value as an input and determining a time point of abnormality of the support unit based on the vibration value; an abnormality pattern storing operation of recognizing and storing, by the inspection unit, a pattern for a current value provided to rotational force of the support unit from the time point of the abnormality of the support unit as an abnormality pattern; and an abnormality pattern detecting operation of updating the abnormality pattern for the current value recognized as the abnormality pattern to the abnormality diagnosis model and determining an abnormality for rotation of the rotation shaft with the abnormality diagnosis model.

According to the exemplary embodiment, the defect detection method may further include an updating operation of updating the abnormality diagnosis model updated in the abnormality pattern detecting operation to other substrate processing units in which the rotation shaft is installed.

According to the exemplary embodiment, the abnormality diagnosis model may have a correlation between the current value and the state of the rotation shaft as data based on a correlation between vibration of the rotation shaft and the state of the rotation shaft and a correlation between the vibration of the rotation shaft and the current value, and determine whether the rotation shaft is defective based on the current value in the data.

According to the exemplary embodiment, the data may include current abnormality patterns formed in a form of a DB.

According to the exemplary embodiment, the rotation shaft may be rotated while being connected to a bearing, and the defect of the rotation shaft may include a defect due to wear with the bearing.

According to the exemplary embodiment, the driver may include a motor, and the abnormality diagnosis model may convert a torque value of the motor into the current value to determine whether the rotation shaft is defective.

According to the exemplary embodiment, the abnormality diagnosis model may detect a time point at which a defect of the rotation shaft occurs by vibration measurement, and recognize a change pattern of the current value from the detected time point as an abnormality pattern to determine whether the rotation shaft is defective.

Still another exemplary embodiment of the present invention provides a substrate processing device for processing a substrate by rotating the substrate, the substrate processing device including a determination unit, in which the determination unit includes: a chamber having a processing space; a plurality of support units for supporting a substrate in the processing space, and supporting the substrate by rotating the substrate; a liquid discharge unit for discharging a chemical liquid in a liquid phase onto a substrate supported on each of the plurality of support units; a liquid supply unit for supplying the chemical liquid to the liquid discharge unit; a vibration detection unit installed on any one of the plurality of support units and measuring a vibration value for the one of the support units; a current detection unit installed in each of the plurality of support units and detecting a current value that rotates the substrate; and an inspection unit for receiving the vibration value and the current value in conjunction with the vibration detection unit and the current detection unit, applying a vibration abnormality diagnosis model to the vibration value to determine an abnormality of rotation of the substrate, and applying an abnormality diagnosis model to the current value from a time point of abnormality at which the abnormality is determined to determine an abnormality of the rotation of the substrate, and the inspection unit may detect a time point at which a defect of the rotation shaft occurs by vibration measurement of the vibration detection unit, and recognizes a change pattern of the current value from the detected time point as an abnormality pattern to determine whether the rotation shaft is defective, and the abnormality diagnosis model may be applied to each of the plurality of support units to determine the abnormality of each of the rotation shafts.

According to the present invention, it is possible to secure an abnormality pattern of a current value compared to a conventional case where it is difficult to determine whether a rotation shaft is defective by analyzing the pattern of the current value alone, so that it is possible to very easily determine whether the rotation shaft is defective based on the current value of the motor alone.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a top plan view illustrating a substrate processing facility according to an exemplary embodiment of the present invention.

FIG. 2 is a cross-sectional view illustrating a substrate processing device of FIG. 1.

FIG. 3 is a block diagram of one example of a determination unit illustrated in FIG. 2.

FIG. 4 is a flowchart illustrating a defect detection method for the substrate processing device according to an exemplary embodiment of the present invention.

FIG. 5 is a graph comparing the time of detecting an abnormality of a rotation shaft with a vibration value and the time of detecting an abnormality of a rotation shaft with a current value in the defect detection method for the substrate processing device illustrated in FIG. 4.

### DETAILED DESCRIPTION

Hereinafter, exemplary embodiments for carrying out the present invention will be described with reference to the accompanying drawings, and in this case, when it is the that a certain constituent element “includes” a certain constituent element throughout the specification, it is considered to mean that it may further include other constituent elements rather than controlling other constituent elements unless otherwise stated. In addition, terms such as “ . . . unit” described in the specification is considered to mean a unit that processes at least one function or operation when describing electronic hardware or electronic software, and mean one component, a function, a use, a point, or a driving element when describing a mechanical device. In addition, hereinafter, the same or similar configurations will be described by using the same reference numerals, and overlapping descriptions of the same constituent elements will be omitted.

Further, when an element or layer is referred to in the present invention as being “on,” “connected to,” “coupled to,” “attached to,” “adjacent to,” or “covering” another element or layer, it may be directly on, connected to, coupled to, attached to, adjacent to, or covering the other element or layer, or intermediate elements or layers may exist. Conversely, when an element is referred to as being “directly on”, “directly connected to”, or “directly bonded to” another element or layer, it is to be understood that no intervening elements or layers are present. Throughout the specification, the same reference numeral refers to the same element. The term “and/or” as used in the present invention further includes all combinations and sub-combinations of one or more of the enumerated items.

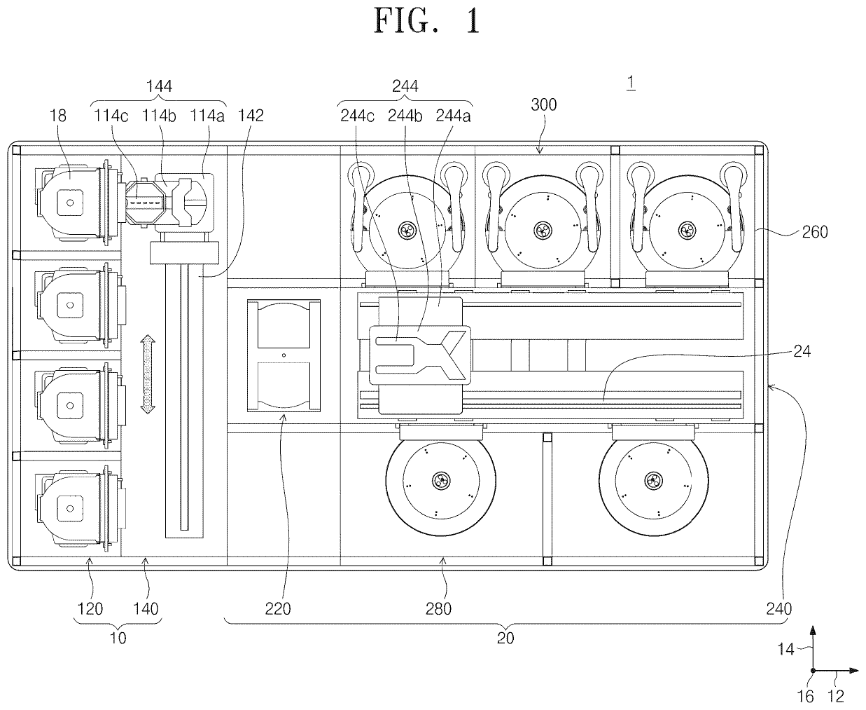

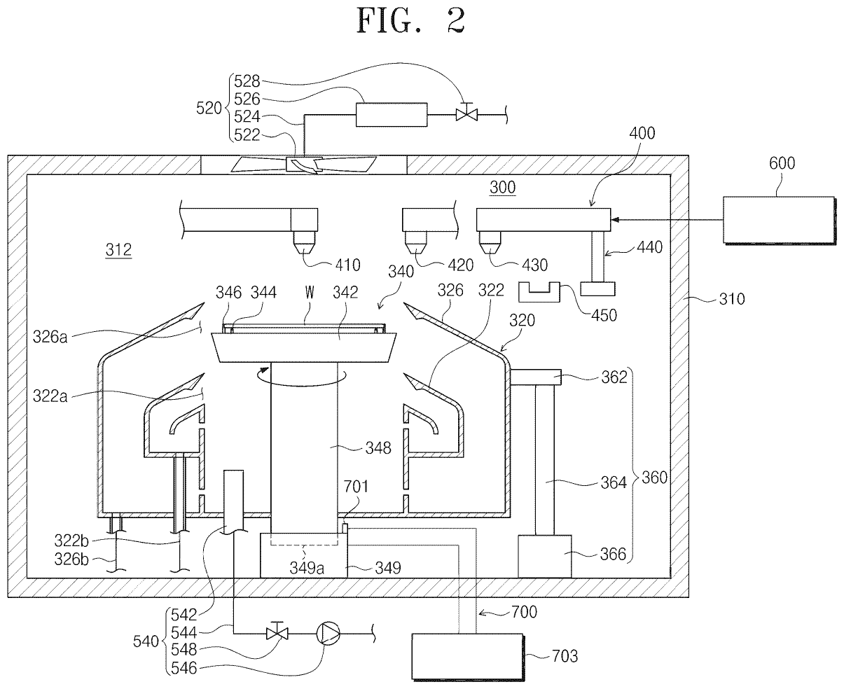

FIG. 1 is a top plan view illustrating a substrate processing facility according to an exemplary embodiment of the present invention. FIG. 2 is a cross-sectional view illustrating a substrate processing device of FIG. 1.

Referring to FIGS. 1 and 2, a substrate processing facility 1 includes an index module 10 and a process processing module 20, and the index module 10 includes a load port 120 and a transfer frame 140. The load port 120, the transfer frame 140, and the process processing module 20 are arranged in sequential rows. Hereinafter, a direction in which the load port 120, the transfer frame 140, and the process processing module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 18 in which a substrate W is accommodated is seated on the load port 120. A plurality of load ports 120 is provided, which are arranged in a row along the second direction 14. In FIG. 1, it is illustrated that four load ports 120 are provided. However, the number of load ports 120 may be increased or decreased depending on conditions, such as process efficiency and footprint of the process processing module 20. Slots (not illustrated) provided to support an edge of the substrate are formed in the carrier 18. The slots are provided in a plurality in the third directions 16, and the substrates are located in a carrier to be stacked while being spaced apart from each other along the third directions 16. As the carrier 18, a Front Opening Unified Pod (FOUP) may be used.

The process processing module 20 may include a buffer unit 20, a transfer chamber 240, and process chambers 260 and 280. The transfer chamber 240 is disposed so that a longitudinal direction thereof is parallel to the first direction 12. The process chambers 260 and 280 are disposed on opposite sides of the transfer chamber 240 in the second direction 14. The process chambers 260 may be provided to be symmetrical to each other relative to the transfer chamber 240. Some of the process chambers 260 and 280 are disposed along the longitudinal direction of the transfer chamber 240. Additionally, some of the process chambers 260 and 280 are arranged to be stacked on top of each other. That is, the process chambers 240 may be disposed in an array of A×B (A and B are natural numbers equal to or greater than 1) on opposite sides of the transfer chamber 240. Here, A is the number of process chambers 260 and 280 provided in a line along the first direction 12, and B is the number of process chambers 260 and 280 provided in a line along the third direction 16. When four or six process chambers 260 are provided on each of the opposite sides of the transfer chamber 240, the process chambers 260 and 280 may be disposed in an array of 2×2 or 3×2. The number of process chambers 260 and 280 may be increased or decreased. Unlike the foregoing, the process chamber 260 may be provided only to one side of the transfer chamber 240. In addition, the process chambers 260 and 280 may be provided as a single layer on one side and the opposite sides of the transfer chamber 240. In addition, the process chambers 260 and 280 may be provided in various arrangements unlike the above.

The process chambers 260 and 280 of the present exemplary embodiment may be categorized as including a cleaning chamber and a drying chamber. In this case, the cleaning chamber may be a substrate processing facility for cleaning the substrate, which will be described below, and the drying chamber may be a substrate processing facility for drying the substrate.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. The buffer unit 220 is provided with slots (not illustrated) in which the substrate W is placed therein, and the slots (not illustrated) are provided in plural to be spaced apart from each other along the third direction 16. In the buffer unit 220, a side facing the transfer frame 140 and a side facing the transfer chamber 240 are each open.

The transfer frame 140 transfers the substrate W between the carrier 18 seated at the load port 120 and the buffer unit 220. The transfer frame 140 is provided with an index rail 142 and an index robot 144. The index rail 142 is provided so that a longitudinal direction thereof is parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 18, and another some of the plurality of index arms 144c may be used when the substrate W is transferred from the carrier 130 to the process processing module 20. This may prevent the particles generated from the substrate W before the process processing from being attached to the substrate W after the process processing in the process in which the index robot 144 loads and unloads the substrate W.

The transfer chamber 240 transfers the substrate W between the buffer unit 220 and the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b.

Hereinafter, a substrate processing device 300 provided in the process chamber 260 will be described. In the present exemplary embodiment, the case where the substrate processing device 300 performs a liquid treating process on the substrate will be described as an example. The liquid treating process further includes a process of cleaning a substrate.

FIG. 2 is a cross-sectional view illustrating a substrate processing device of FIG. 1. Referring to FIG. 2, the substrate processing device 300 further includes a chamber 310, a processing container 320, a support unit 340, a lifting unit 360, a liquid discharge unit 400, an airflow formation unit 500, a liquid supply unit 600, and a controller 900. The chamber 310 provides a processing space 312 in which a process for processing the substrate W is performed.

The processing container 320 is positioned in the processing space 312 and is provided in the shape of a cup with an open top. When viewed from above, the processing container 320 is positioned to overlap an exhaust pipe. The processing container 320 includes an internal collection container 322 and an external collection container 326. Each of the collection containers 322 and 326 collects a different treatment solution from the treatment solutions used in the process. The internal collection container 322 is provided in the shape of an annular ring surrounding the support unit 340, and the external collection container 326 is provided in the shape of an annular ring surrounding the inner collection container 322. An inner space 322a of the internal collection container 322 and a space 326a between the external collection container 326 and the internal collection container 322 function as inlets for the treatment solution to flow into the internal collection container 322 and the external collection container 326, respectively. Collection lines 322b and 326b are connected to the bottom surfaces of the collection containers 322 and 326, respectively, to extend vertically in the down direction. Each of the collection lines 322b and 326b functions as a discharge pipe to discharge the treatment solution that has been introduced through the respective collection containers 322 and 326. The discharged treatment solution may be reused through an external treatment solution regeneration system (not illustrated).

The support unit 340 is provided as a substrate support unit 340 for supporting and rotating the substrate W. The support unit 340 is disposed within the processing container 320. The substrate support unit 340 supports the substrate W and rotates the substrate W during the process progress. The support unit 340 includes a spin chuck 342, a support pin 344, a chuck pin 346, and a rotation shaft 348. The spin chuck 342 has a top surface that is substantially circular when viewed from the top. The rotation shaft 348 that is rotatable by a driver is fixedly coupled to the bottom surface of the spin chuck 342. In one example, the driver may be formed of a motor 349. A plurality of support pins 344 is provided. The support pins 344 are spaced apart on the edge portion of a top surface of the spin chuck 342 and protrude upwardly from the spin chuck 342. The support pins 334 are arranged in combination with each other to have an overall annular ring shape. The support pin 344 supports an edge of the rear surface of the substrate W so that the substrate W is spaced apart from the top surface of the spin chuck 2631 at a predetermined distance. A plurality of chuck pins 346 is provided. The chuck pins 346 are disposed to be further away from a center of the spin chuck 342 than the support pins 344. The chuck pin 346 is provided to protrude upwardly from the spin chuck 342. The chuck pin 346 supports a lateral portion of the substrate W to prevent the substrate W from laterally deviating from its stationary position when the support unit 340 is rotated. The chuck pin 346 is provided to be linearly movable between a standby position and a support position along a radial direction of the spin chuck 342. The standby position is a position further away from the center of the spin chuck 342 relative to the support position. When the substrate W is loaded into or unloaded from the support unit 340, the chuck pin 346 is positioned in the standby position, and when a process is being performed on the substrate W, the chuck pin 346 is positioned in the support position. In the support position, the chuck pin 346 is in contact with the lateral portion of the substrate W.

The lifting unit 360 regulates the relative height between the processing container 320 and the support unit 340. The lifting unit 360 linearly moves the processing container 320 in the upper and lower directions. As the processing container 320 is moved up and down, the relative height of the processing container 320 with respect to the support unit 340 changes. The lifting unit 460 includes a bracket 360, a moving shaft 362, and a driver 364. The bracket 362 is fixedly installed on the outer wall of the processing container 320, and a moving shaft 364, which is moved in the vertical direction by a driver 366, is fixedly coupled to the bracket 364. When the substrate W is placed on the support unit 340 or lifted from the support unit 340, the processing container 320 is lowered so that the support unit 340 protrudes above the processing container 320. In addition, when the process is in progress, the height of the processing container 320 is adjusted so that the treatment solution flows into the preset collection container according to the type of treatment solution supplied to the substrate W.

As described above, the lifting unit 360 may move the support unit 340 in the upper and lower directions instead of the processing container 320.

The liquid discharge unit 400 supplies various types of liquids to the substrate W. The liquid discharge unit 400 further includes a plurality of nozzles 410 to 430. Each nozzle is moved to a process position and a standby position by a nozzle position driver 440. A process position is defined herein as a position where the nozzles 410 to 430 are capable of discharging liquid onto the substrate W positioned within the processing container 320, and a standby position is defined as a position where the nozzles 410 to 430 are waiting outside of the process position. According to an example, the process position may be a position at which the nozzles 410 to 430 may supply a liquid to the center of the substrate W. For example, when viewed from above, the nozzles 410 to 430 may be moved linearly or axially to be moved between the process position and the standby position. The treatment solution discharged from the liquid discharge unit 400 onto the substrate W may be a liquefied treatment solution. Additionally, in the standby position, a collection pipe 450 may be disposed below the third nozzle 430. The collection pipe 450 collects the chemical liquid when the third nozzle 430 discharges the chemical liquid for cleaning.

The plurality of nozzles 410 to 430 discharges different types of liquid. The chemical liquids discharged from the nozzles 410 to 430 may include at least one of a chemical, a rinse solution, and a drying fluid. Referring to the exemplary embodiment of FIG. 2, a first nozzle 410 may be a nozzle for discharging chemicals. A second nozzle 420 may be a nozzle that discharges a rinse solution. A third nozzle 430 may be a nozzle that discharges a drying fluid. For example, the chemical may be a liquid capable of etching a film formed on the substrate W or removing particles remaining on the substrate W. The chemical may be a liquid having a property of strong acid or strong base. The chemical may include sulfuric acid, hydrofluoric acid, or ammonia. The rinse solution may be a solution capable of rinsing the chemicals remaining on the substrate W. For example, the rinse solution may be pure water. The drying fluid may be provided as a liquid capable of replacing the residual rinse solution on the substrate W. The drying fluid may be a liquid having lower surface tension than the rinse solution. The drying fluid may be an organic solvent. The drying fluid may be isopropyl alcohol (IPA). The third nozzle 430 may be connected to the liquid supply unit 600 to be described later.

The airflow forming unit 500 forms a downward airflow in the processing space 312. The airflow forming unit 500 supplies airflow from an upper portion of the chamber 310 and exhausts airflow from a lower portion of the chamber 310. The airflow forming unit 500 further includes an airflow supply unit 520 and an exhaust unit 540. The airflow supply unit 520 and the exhaust unit 540 are positioned facing each other in the vertical direction.

The airflow supply unit 520 supplies gas in the downward direction. The gas supplied from the airflow supply unit 520 may be air from which impurities are removed. The airflow supply unit 520 further includes a fan 522, an airflow supply line 524, a supply valve 528, and a filter 526. The fan 522 is installed on the ceiling surface of the chamber 310. When viewed from above, the fan 522 is positioned to face the processing container. The fan 522 may be positioned to provide air toward the substrate W positioned within the processing container. The airflow supply line 524 is connected to the fan 522 to supply air to the fan 522. A supply valve 528 is installed in the airflow supply line 524 to regulate the amount of airflow supplied. The filter 526 is installed in the airflow supply line 524 to filter the air. For example, the filter 526 may remove particles and moisture contained in the air.

The exhaust unit 540 exhausts the processing space 312. The exhaust unit 540 further includes an exhaust pipe 542, a pressure reducing member 546, and an exhaust valve 548. The exhaust pipe 542 is installed on the bottom surface of the chamber 310 and is provided as a pipe to exhaust the processing space 312. The exhaust pipe 542 is positioned such that the exhaust port faces upwardly. The exhaust pipe 542 is positioned such that the exhaust port is in communication with the interior of the processing container. That is, the top of the exhaust pipe 542 is located within the processing container. Accordingly, the downward airflow formed within the processing container is exhausted through the exhaust pipe 542.

The pressure reducing member 546 reduces pressure of the exhaust pipe 542. A negative pressure is formed in the exhaust pipe 542 by the pressure reducing member 546, which exhausts the processing container. The exhaust valve 548 is installed in the exhaust pipe 542 and opens and closes the exhaust port of the exhaust pipe 542. The exhaust valve 548 regulates the exhaust volume.

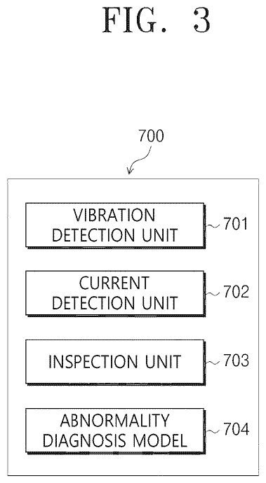

FIG. 3 is a block diagram of one example of a determination unit illustrated in FIG. 2.

Referring further to FIG. 3, the substrate processing device according to the exemplary embodiment of the present invention may further include a bearing 349a and a determination unit 700.

The bearing 349a is installed on at least one of a lower surface and an outer circumference of the rotation shaft 348. In this case, the bearing 349a may be configured to be included in the support unit 340. The bearing 349a may rotate in connection with the rotation shaft 348 upon rotation of the rotation shaft 348, thereby supporting the rotation shaft 348 while reducing frictional force on the rotation shaft 348. In this case, the bearing 349a is consumable and wears out when the rotation shaft 348 rotates, which may cause dust in a vibrating state.

The determination unit 700 determines whether the rotation shaft 348 is defective based on a current value applied to a driver while the rotation shaft 348 is rotating. Here, the defect of the rotation shaft 348 is determined in a state in which the rotation shaft 348 vibrates abnormally and the vibration value increases by a preset value or more. In this case, the defect of the rotation shaft 348 may be a vibration caused by wear of the bearing 349a.

Here, the determination unit 700 may receive a current value in real time from the driver formed of the motor 349. Alternatively, the determination unit 700 may receive an input of a torque value of the motor 349 and convert the torque value to a current value, thereby receiving an input of a current value of the motor 349 without the configuration computing the current value.

Meanwhile, the determination unit 700 for determining whether the rotation shaft 348 is defective may further include an abnormality diagnosis model 704 in which a relationship between a current value and a state of the rotation shaft 348 is preset. In this case, the abnormality diagnosis model 704 may store data of various current abnormality patterns of the current values when the vibration increases by the preset value or more in the form of a database, and continuously determine whether the data of the current pattern corresponds to the current abnormality pattern. The abnormality diagnosis model 704 can detect the abnormality of the rotation shaft 348 and replace the rotation shaft 348 when the current pattern corresponds to the current abnormality pattern due to the abnormality of the rotation shaft 348, thereby preventing dust from being generated between the rotation shaft 348 and the bearing 349a. Thus, by determining the defect in the rotation shaft 348, the substrate processing device according to the exemplary embodiment of the present invention can prevent dust generated by the rotation shaft 348 from entering the substrate W during process processing.

In this case, in storing the data of the current abnormality pattern in the form of a DB, the abnormality diagnosis model 704 may set a detection time point for the data of the current abnormality pattern based on a time point at which the defect of the rotation shaft 348 is generated by the vibration measurement. In this case, the abnormality diagnosis model 704 determines the defect by determining whether the measured vibration corresponds to the data of a vibration abnormality pattern when the defect of the rotation shaft 348 is determined by the vibration measurement. In this case, the abnormality diagnosis model 704 may store the data of the vibration abnormality pattern in the form of a DB, and determine whether the vibration abnormality pattern in the DB corresponds to the measured vibration value to determine a defect of the rotation shaft 348. In other words, the abnormality diagnosis model 704 sets a detection tie point for the data of the current abnormality pattern by using a correlation between the vibration of the rotation shaft 348 and the state of the rotation shaft 348. Thus, because the abnormality diagnosis model 704 determines whether the rotation shaft 348 is defective from the time point at which the vibration occurs when detecting the abnormality of the rotation shaft 348, the abnormality diagnosis model 704 is not unnecessarily driven at a time when the rotation shaft 348 is rotating normally, thereby reducing the load factor of the determination unit 700. Furthermore, because the abnormality diagnosis model 704 accurately determines and detects the time point at which the rotation shaft 348 has defect by vibration measurement, the abnormality diagnosis model 704 can more accurately determine whether the rotation shaft 348 has abnormality.

As one example of the determination unit 700, the determination unit 700 may further include a vibration detection unit 701, a current detection unit 702, and an inspection unit 703.

The vibration detection unit 701 may be installed on the support unit 340 to measure the vibration value of the support unit 340. In this case, the vibration detection unit 701 may include any one of an acceleration sensor, a displacement sensor, and an acoustic sensor. When the vibration detection unit 701 is configured as an acceleration sensor, the vibration detection unit 701 may measure a vibration value generated when the support unit 340 vibrates by measuring the acceleration of the vibration of the support unit 340. Further, when the vibration detection unit 701 is configured as a displacement sensor, such as a laser sensor, the vibration detection unit 701 can measure a vibration value generated when the support unit 340 vibrates by measuring the amount of displacement in response to the vibration of the support unit 340. Furthermore, when the vibration detection unit 701 is configured as an acoustic sensor, the vibration detection unit 701 can measure a vibration value generated when the support unit 340 vibrates by measuring the displacement of the surface tremor of the support unit 340 with acoustic waves.

The current detection unit 702 may be electrically connected to the support unit 340 to detect a current value applied to the motor 349 that rotates the support unit 340. In this case, the current detection unit 702 may measure the current value of the motor 349 in real time, as in the example described above, or may measure the torque value of the motor 349 by converting the torque value to a current value. In the case of converting the torque value of the motor 349 to the current value, the torque value may be converted to the current value by multiplying the input torque value by a conversion rate constant.

The inspection unit 703 may include a device that includes control functions and signal processing functions, such as a controller or DAQ. Accordingly, the inspection unit 703 may convert the analog signal value measured by the vibration detection unit 701 to a digital signal value, and analyze the converted digital signal value with the abnormality diagnosis model 704. Specifically, the inspection unit 703 may receive vibration values and current values from the vibration detection unit 701 and the current detection unit 702 as inputs, and continuously store and record the input vibration values and current values. In this case, the inspection unit 703 determines a rotation error of the support unit 340 based on the vibration value input to the vibration detection unit 701. The inspection unit 703 may use the abnormality diagnosis model 704 to determine a rotation error of the support unit 340. The abnormality diagnosis model 704 may determine that the rotation shaft 348 has a vibration abnormality when the pattern of the input vibration values matches or approaches within a certain range a vibration abnormality pattern stored in the form of the DB. In this case, the inspection unit 703 applies the abnormality diagnosis model 704 to the current value from an abnormality time t01 determined by the rotation error of the support unit 340 to determine the abnormality of the rotation of the substrate W. In this case, the abnormality diagnosis model 704 may store various current abnormality patterns of the current values when the vibration increases by a set value or more in the form of the DB as described above, and continuously determine whether the current pattern corresponds to the current abnormality pattern. In this case, the abnormality diagnosis model 704 can more accurately determine the abnormality in the rotation shaft 348 because the abnormality diagnosis model 704 accurately determines and detects the time point at which the rotation shaft 348 has the defect by the vibration measurement.

In the following, a defect detection method for the substrate processing device as described above will be described.

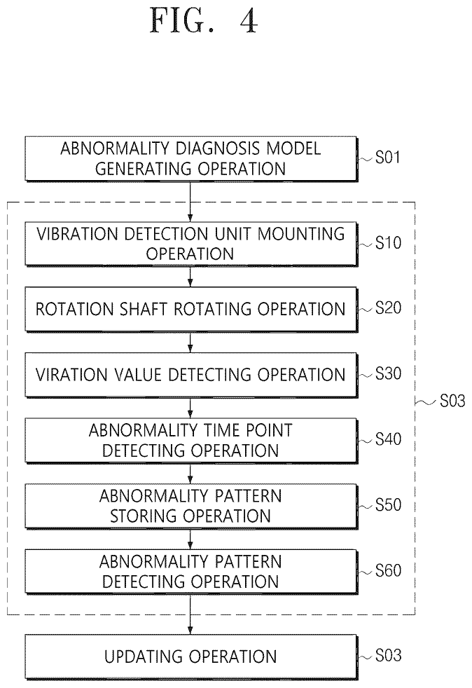

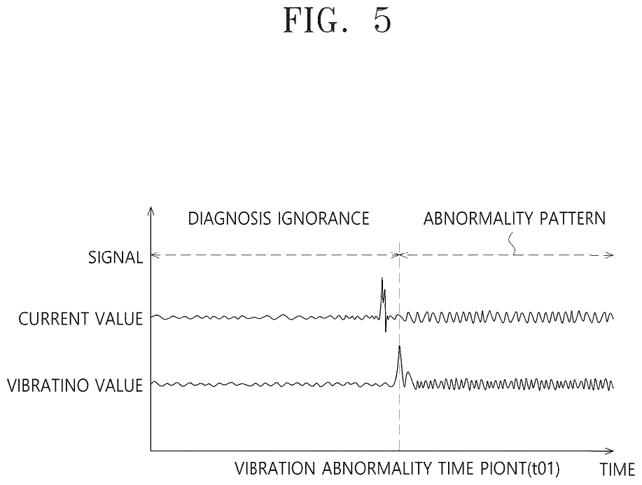

FIG. 4 is a flowchart illustrating a defect detection method for the substrate processing device according to an exemplary embodiment of the present invention. FIG. 5 is a graph comparing the time of detecting an abnormality of the rotation shaft with a vibration value and the time of detecting an abnormality of the rotation shaft with a current value in the defect detection method for the substrate processing device illustrated in FIG. 4.

Referring further to FIG. 5, a defect detection method for the substrate processing device according to the exemplary embodiment of the present invention includes: generating a defect diagnosis model 704 based on a preset correlation between a current value of the motor 349, which is a driver, and a state of the rotation shaft 348 (S01); determining, by the abnormality diagnosis model 704, whether the rotation shaft 348 is defective based on the current value applied to the motor 349 that rotates the rotation shaft 348 while the rotation shaft 348 is rotating (S02); and updating the defect diagnosis model 704 to the respective substrate processing device (S03).

First, operation S01 of generating the abnormality diagnosis model 704 may include a vibration detection unit mounting operation S10, a rotation shaft rotating operation S20, a vibration value detecting operation S30, an abnormality time detecting operation S40, an abnormality pattern storing operation S50, and an abnormality pattern detecting operation S60.

In the vibration detection unit mounting operation S10, the vibration detection unit 701 is mounted on the support unit 340 including the rotation shaft 348. Here, the vibration detection unit 701 may be equipped with an acceleration sensor, a displacement sensor, and an acoustic sensor as described above.

In the rotation shaft rotating operation S20, the rotation shaft 348 is rotated. In this case, the rotation shaft 348 may be driven by the motor 349, which is a driver as described above, and the rotation shaft 348 may be rotated with the bearing 349a connected to the rotation shaft 348.

In the vibration value detecting operation S30, the vibration detection unit 701 may detect the vibration value of the rotation shaft 348.

In the abnormality time detection operation S40, the vibration value is input to the inspection unit 703, and an abnormality time t01 of the support unit 340 is determined by the vibration value. Herein, as described above, it may be determined that the rotation shaft 348 has a vibration abnormality when the pattern of the input vibration values matches or approaches within a certain range a vibration abnormality pattern stored in the form of the DB.

In the abnormality pattern storing operation S50, the inspection unit 703 recognizes and stores a pattern of the current value provided to rotational force of the support unit 340 from the abnormality time t01 of the support unit 340 as an abnormality pattern.

In the abnormality pattern detecting operation S60, the abnormality pattern of the current value recognized as the abnormality pattern is updated to the abnormality diagnosis model 704 to determine the abnormality of the rotation of the rotation shaft 348 with the abnormality diagnosis model 704. Thus, the abnormality diagnosis model 704 may determine the abnormality of the rotation shaft 348 just by analyzing the current values.

In the update operation S03, the abnormality diagnosis model 704 updated in the abnormality pattern detecting operation S60 is updated to other substrate processing devices on which the rotation shaft 348 is installed. In this case, the other substrate processing devices can detect the abnormality of the rotation shaft 348 based only on the current value of the motor 349 even when the vibration detection unit 701 is not installed.

Thus, in the substrate processing device and the defect detection method for the substrate processing device according to the exemplary embodiment of the present invention, when the current value is used to determine the defect of the rotation shaft 348, the time when the defect occurs is recognized from the measured vibration value, and the pattern of the current value from the time when the defect occurs is recognized as an abnormality pattern and stored in the abnormality diagnosis model 704 in the form of a DB. In this case, the abnormality diagnosis model 704 updates the abnormality pattern for each case of failure of the rotation shaft 348 that has a different set of failure symptoms, thereby detecting more diverse types of defects.

Therefore, the substrate processing device and the defect detection method for the substrate processing device according to the exemplary embodiment of the present invention can secure an abnormality pattern of the current value compared to a conventional case where it is difficult to determine whether the rotation shaft 348 is defective by analyzing the pattern of the current value alone, so that it is possible to very easily determine whether the rotation shaft 348 is defective based on the current value of the motor 349 alone.

While the substrate processing device according to the exemplary embodiment of the present invention has been described primarily by way of example for a cleaning process, it is of course that the substrate processing device according to the exemplary embodiment of the present invention are applicable to an etching process as well. In other words, although the present invention has been described above with reference to specific matters such as specific components and the like, and with reference to limited exemplary embodiments and drawings, these are provided for a more general understanding of the invention, the invention is not limited to the above exemplary embodiments, and various modifications and variations may be made from these descriptions by those skilled in the art to which the invention belongs.

Therefore, the spirit of the present invention should not be limited to the described exemplary embodiments, and it will be the that not only the claims to be described later, but also all modifications equivalent to the claims belong to the scope of the present invention.

1. A device for processing a substrate, the device comprising:
a support unit including a spin chuck supporting a substrate, a rotation shaft supporting the spin chuck, and a driver providing rotational force to the rotation shaft; and
a determination unit for determining whether the rotation shaft is defective,
wherein the determination unit determines whether the rotation shaft is defective based on a current value applied to the driver while the rotation shaft is rotating.

2. The device of claim 1, wherein the determination unit includes an abnormality diagnosis model in which a relationship between the current value and a state of the rotation shaft is preset, and
whether the rotation shaft is defective is determined by the abnormality diagnosis model.

3. The device of claim 2, wherein the abnormality diagnosis model has a correlation between the current value and the state of the rotation shaft as data based on a correlation between vibration of the rotation shaft and the state of the rotation shaft and a correlation between the vibration of the rotation shaft and the current value, and determines whether the rotation shaft is defective based on the current value in the data.

4. The device of claim 3, wherein the data includes current abnormality patterns formed in a form of a DB.

5. The device of claim 3, wherein the support unit further includes a bearing connected to the rotation shaft, and
the defect in the rotation shaft includes a defect due to wear with the bearing.

6. The device of claim 1, wherein the driver includes a motor, and
the determination unit detects a torque value of the motor, converts the torque value to a current value, and determines whether the rotation shaft is defective.

7. The device of claim 2, wherein the abnormality diagnosis model detects a time point at which a defect of the rotation shaft occurs by vibration measurement, and
recognizes a change pattern of the current value from the detected time point as an abnormality pattern to determine whether the rotation shaft is defective.

8. The device of claim 7, wherein a vibration value measured when measuring the vibration is measured by an acceleration for vibration of the support unit.

9. The device of claim 7, wherein a vibration value measured when measuring the vibration is measured by the amount of displacement for vibration of the support unit.

10. The device of claim 7, wherein a vibration value measured when measuring the vibration is measured by a sound generated by the vibration of the support unit.

11. The device of claim 1, wherein the determination unit includes:
a vibration detection unit installed on the support unit to measure a vibration value of the support unit;
a current detection unit electrically connected with the support unit to detect a current value applied to a motor rotating the support unit; and
an inspection unit that receives the vibration value and the current value from the vibration detection unit and the current detection unit as inputs, determines an error in rotation of the support unit based on the vibration value, and determines an abnormality in rotation of the substrate by applying an abnormality diagnosis model to the current value from a time point at which the error in rotation of the support unit is determined.

12.-19. (canceled)

20. A substrate processing device for processing a substrate by rotating the substrate, the substrate processing device comprising:
a determination unit,
wherein the determination unit includes:
a chamber having a processing space;
a plurality of support units for supporting a substrate in the processing space, and
supporting the substrate by rotating the substrate;
a liquid discharge unit for discharging a chemical liquid in a liquid phase onto a substrate supported on each of the plurality of support units;
a liquid supply unit for supplying the chemical liquid to the liquid discharge unit;
a vibration detection unit installed on any one of the plurality of support units and measuring a vibration value for the one of the support units;
a current detection unit installed in each of the plurality of support units and detecting a current value that rotates the substrate; and
an inspection unit for receiving the vibration value and the current value in conjunction with the vibration detection unit and the current detection unit, applying a vibration abnormality diagnosis model to the vibration value to determine an abnormality of rotation of the substrate, and applying an abnormality diagnosis model to the current value from a time point of abnormality at which the abnormality is determined to determine an abnormality of the rotation of the substrate, and
the inspection unit detects a time point at which a defect of the rotation shaft occurs by vibration measurement of the vibration detection unit, and recognizes a change pattern of the current value from the detected time point as an abnormality pattern to determine whether the rotation shaft is defective, and
the abnormality diagnosis model is applied to each of the plurality of support units to determine the abnormality of each of the rotation shafts.
